(19) United States
(12) Patent Application Publication
(10) Pub. No.: US 2007/0075797 A1
(43) Pub. Date: Apr. 5, 2007

(54) Method of manufacturing crystal oscillator and the crystal oscillator manufactured by the method

(75) Inventors: Yuichi Matsuya, Chiba (JP); Ryuji Ariyoshi, Chiba (JP)

Correspondence Address: OLIFF & BERRIDGE, PLC, P.O. BOX 19928, ALEXANDRIA, VA, 22320, US

(73) Assignee: KAWASAKI MICROELECTRONICS, INC., CHIBA (JP)

(21) Appl. No.: 11/541,559

(22) Filed: Oct. 3, 2006

(30) Foreign Application Priority Data
Oct. 3, 2005 (JP) 2005-289654

(51) Int. Cl. H03B 5/32

(52) U.S. Cl. 331/158

(57) ABSTRACT

The method of manufacturing a crystal oscillator that is compensated for temperature with low-cost, and a crystal oscillator that is compensated for temperature by the method is disclosed. A plurality of crystal oscillators are manufactured by preparing a compensation circuit that generates a common compensation voltage in accordance with a predetermined compensation curve expressed by a quintic polynomial of an ambient temperature; and manufacturing each of the plurality of crystal oscillators by integrating the compensation circuit with a voltage controlled oscillation circuit including a crystal resonator, the common compensation voltage generated by the compensation circuit being supplied to the voltage controlled oscillation circuit so that the temperature characteristic of the crystal resonator is compensated.

### CROSS-REFERENCE TO RELATED APPLICATIONS

Exemplary embodiments of this invention were first described in and claim priority from Japanese Application No. 2005-289654, which is incorporated by reference in its entirety.

### BACKGROUND

This invention relates to a method of manufacturing a temperature compensated crystal oscillator and the crystal oscillator manufactured by the method.

The demand for crystal oscillators that utilize crystal resonators is recently increasing as signal generators that supply constant frequency signals or clock signals to electronic equipments such as electric telecommunication equipments and the like. Several kinds of crystal oscillators that utilize crystal resonators are commercialized. One of them is the Simple Packaged Crystal Oscillator (SPXO), and another is the Temperature Compensated Crystal Oscillator (TCXO).

SPXO is a crystal oscillator that is neither controlled nor compensated for the ambient temperature. On the other hand, the TCXO is equipped with a circuit that compensates for the ambient temperature. TCXO suppresses the change of frequency of the output signal due to the ambient temperature. These crystal oscillators are generally used according to the specific purpose or the required accuracy of a given use.

It is well known that the temperature characteristic of the crystal resonator used for the crystal oscillator is different according to the cutting directions of the crystal resonator. An “AT-cut crystal resonator” is most widely used.

The AT-cut crystal resonator has a primarily cubic temperature characteristic. Accordingly, in order to suppress the frequency fluctuation of a crystal oscillator (an oscillator employing an AT-cut crystal resonator) due to change in the ambient temperature, the following methods are usually applied:

(1) In the case of the SPXO, the usable temperature range of the crystal oscillator is specified within a narrow range, and the cutting angle of the crystal resonator is set in accordance with the specified usable temperature range, so that the fluctuation of the oscillation frequency is reduced.

(2) In the case of the TCXO, the oscillation circuit is constructed as a Voltage Controlled Crystal Oscillator (VCXO) circuit. Moreover a temperature compensation circuit is integrated in the VCXO circuit, so that a compensation voltage is generated that is suitable for compensating or canceling a change in the resonance frequency of the individual crystal resonator.

In the method (1), however, the oscillation frequency fluctuates within a range of approximately ±30 ppm, when the temperature range for operation is set to be from −40° C. to +85° C., which is the standard temperature range for the crystal oscillator. Alternatively, the temperature range is narrowly limited when the oscillation frequency is required to be controlled within a narrower range.

In order to implement method (2), on the other hand, Reference 1 (Japanese Laid-open Gazette No. 9-55624), for instance, specifically discloses the following method: The temperature characteristic of a crystal resonator can be approximated by the sum of a cubic function and a linear function. A temperature detection circuit detects the ambient temperature and outputs a voltage that changes linearly with the ambient temperature. The detected output voltage, which is described as a linear function of temperature, is transformed into a cubic function of temperature, which is approximated to the cubic component of the temperature characteristics of a crystal resonator. Then, a signal generation circuit adds the linear function and the cubic function in order to form a control signal for VCXO circuit.

Reference 2 (Japanese Laid-open Gazette No. 2004-272882) further discloses a TCXO, which is equipped with a compensation circuit that generates a compensation voltage according to a function including cubic and additional terms. The additional terms may be a constant, a linear, a cubic or a quintic term.

The second method is very effective in suppressing the frequency fluctuation because it makes possible the accurately compensation of the characteristic of the crystal resonator. Typically, the range of frequency fluctuation can be reduced to ±2.5 ppm within a temperature range of −40° C. to +85° C. It is necessary, however, to measure the frequency characteristic of each crystal resonator in order to adjust the compensation curve of the compensation circuit. Therefore, the second method has a problem in that it requires a long time for the measurement and the adjustment, which significantly increases the manufacturing cost.

### SUMMARY

There is a strong and real demand in the market for crystal oscillators with a specification that cannot be satisfied by either of the SPXO and the TCXO. In fact, while a frequency fluctuation, within the temperature range of −40° C. to +85° C., of approximately ±10 ppm is acceptable, a low cost for the crystal oscillator is also required. In the above-described example, the SPXO crystal oscillator cannot satisfy the specification and the high cost of the TCXO crystal oscillator is not acceptable.

In order to solve the above-mentioned problems, a method of manufacturing a crystal oscillator that is compensated for temperature with low-cost is provided, and a crystal oscillator which is compensated for temperature by that method.

An exemplary method of manufacturing a crystal oscillator compensated for temperature at low-cost, and an exemplary crystal oscillator compensated for temperature by that exemplary method is disclosed. According to an exemplary method of manufacturing a crystal oscillator, a plurality of crystal oscillators are manufactured by preparing a compensation circuit that generates a common compensation voltage in accordance with a predetermined compensation curve expressed by, for example, a quintic polynomial of an ambient temperature. The exemplary method also includes manufacturing each of the plurality of crystal oscillators by integrating the compensation circuit with a voltage controlled oscillation circuit that includes a crystal resonator having a primarily cubic temperature characteristic, the common compensation voltage generated by the compensation circuit being supplied to the voltage controlled oscillation circuit so that the temperature characteristic of the crystal resonator is compensated. A crystal oscillator, according to another exemplary embodiment, comprises a voltage controlled crystal oscillation circuit that includes a crystal resonator having a primarily cubic temperature characteristic and a compensation circuit that generates a compensation voltage for compensating the temperature characteristic of the crystal resonator, the compensation voltage being supplied to the voltage controlled crystal oscillation circuit, wherein the compensation circuit may only be composed of a quintic function circuit that generates a voltage having a primarily quintic characteristic of an ambient temperature.

According to various exemplary embodiments, the common compensation voltage generated by the compensation circuit is commonly used for compensating a plurality of temperature compensated crystal oscillators, which is different from conventional temperature compensated crystal oscillators.

### BRIEF DESCRIPTION OF THE DRAWINGS

FIG. 1 shows an example illustrating a block diagram of functions according to an exemplary embodiment of the crystal oscillators;

FIG. 2 shows an example illustrating a circuit diagram that includes a circuit layout to generate compensation voltage according to an exemplary embodiment;

FIG. 3 shows examples of simulation results in which the temperature characteristics of crystal resonators are compensated by compensation curves;

FIG. 4 shows an example illustrating a block diagram of functions to set the coefficients of α and γ of compensation curves according to an exemplary embodiment of the crystal oscillators;

FIG. 5 shows an example illustrating a diagram of IC composition according to an exemplary embodiment of the crystal oscillators.

### DETAILED DESCRIPTION OF EMBODIMENTS

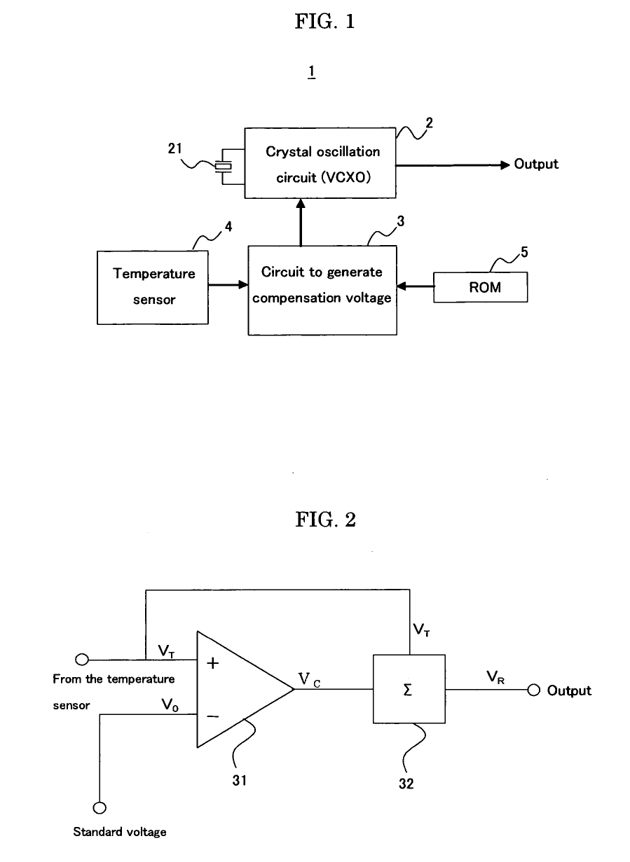

FIG. 1 shows an example illustrating a block diagram of an exemplary embodiment of the crystal oscillator. As shown in FIG. 1, a crystal oscillator 1, according to an exemplary embodiment, comprises a VCXO circuit 2, a circuit to generate a compensation voltage 3 and a temperature sensor 4.

The exemplary circuit to generate the compensation voltage 3 compensates the temperature characteristic of the crystal resonator 2 by generating a compensation voltage according to a predetermined compensation curve that includes a quintic term. The word “predetermined” means that the compensation curve may be decided before assembling the crystal resonator with the oscillation circuit and without measuring the temperature characteristic of the crystal resonator to be assembled.

Accordingly, in contrast to the TCXO, the crystal oscillator according to this exemplary embodiment can be manufactured without any measurement of the temperature characteristic of the crystal resonator, and without any adjustment of the compensation curve of the compensation circuit. As a result, the crystal oscillator according to this exemplary embodiment can be manufactured at a significantly lower cost compared to the TCXO.

FIG. 2 shows an exemplary circuit layout of the circuit to generate the compensation voltage 3. As shown in FIG. 2, the exemplary circuit to generate the compensation voltage 3 can be composed of a comparator 31 and an accumulator 32. An output signal VT from the temperature sensor 4, which indicates the temperature around the crystal resonator 21, and the reference voltage V0, are input into the comparator 31. The output signal VC from the comparator 31 is input into the accumulator 32. The compensation signal VR is an output of the accumulator 32 and is a result of the accumulation of the output signal VC from the comparator 31 and the output signal VT from the temperature sensor 4.

Based on the predetermined compensation curve that includes a quintic term, a compensation voltage corresponding to the ambient temperature of the crystal resonator 21, which is measured by the temperature sensor 4, is generated. In an exemplary embodiment of the crystal oscillator, the compensation curve including a quintic term is predetermined, i.e., the compensation curve is not adjusted for each individual crystal resonator.

To meet the demand of a customer, a plurality of crystal oscillators are manufactured using a plurality of crystal resonators. Although resonators are prepared according to the same specification, the temperature characteristics of the individual resonators are not exactly the same. Nonetheless, the same compensation curve predetermined for the customer can be used in the plurality of crystal oscillators. As a result, labor required for adjusting the compensation curve for each crystal resonator, which takes a lot of labor time, may be avoided. Accordingly, it is possible to offer the crystal oscillator at a low cost.

The crystal oscillator 1 according to an exemplary embodiment has only one circuit that generates the compensation voltage, as shown in FIG. 2. The circuit generates a compensation voltage having primarily a quintic characteristic, i.e., the circuit generates the compensation voltage according to a compensation curve having a quintic term as the dominant term. That is, in the exemplary crystal oscillator 1, there are no other circuits that generate the compensation voltage. Specifically, the exemplary crystal oscillator 1 may not include a compensation circuit that generates a compensation voltage having a cubic characteristic according to a compensation curve that includes a cubic term as the dominant term.

According to various exemplary embodiments, the compensation circuit shown in FIG. 2 does not necessarily have to generate a compensation voltage according to a compensation curve that only has the quintic term. The compensation curve may also have other terms. In practice, it is generally difficult to construct a compensation circuit that generates purely a quintic characteristic. Nonetheless, the compensation circuit 2 generates a compensation voltage that has primarily a quintic characteristic. This exemplary compensating method is quite different from the method of “the control technology of higher dimensions such as quartic and quintic are needed, when the accuracy for the temperature compensating is required to be much higher” disclosed in the paragraph of [0006] in Reference 2.

The method described in Reference 2 primarily compensates a cubic characteristic of a crystal resonator with a compensation voltage having a cubic characteristic. In addition to the primarily cubic compensation voltage, the method described in Reference 2 further compensates using a compensation voltage having quartic and quintic characteristic in order to achieve a higher accuracy. In other words, the circuit of FIG. 1 in Reference 2 discloses “the circuit that generates a compensation voltage of primarily a cubic characteristic, according to a compensation curve that includes a cubic term as a dominant term and includes additionally a quintic term.” Therefore, the essential idea of the present exemplary embodiment, i.e. “the circuit that generates the compensation voltage of primarily a quintic characteristic”, is quite different from the invention disclosed in Reference 2.

The simple circuit layout of the exemplary embodiment shown in FIG. 2 contributes to the low-cost production of the crystal oscillator.

According to various exemplary embodiments, the circuit to generate compensation voltage 3, which generates the compensation voltage according to a compensation curve including a quintic term, makes it possible to offer the crystal oscillator that satisfies the required specification at a low-cost without adjusting the compensation curve for each individual crystal resonator. According to various exemplary embodiments, it is assumed that the fluctuation margin of the oscillation frequency required for the crystal oscillator is within ±10 ppm in the temperature range of −40° C. to +85° C.

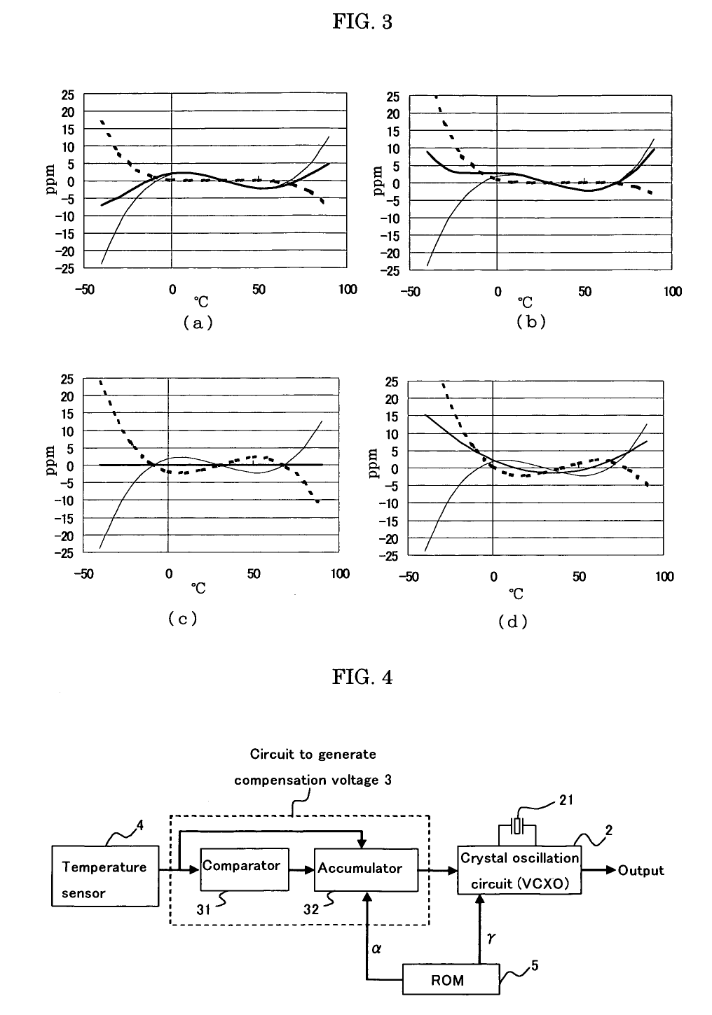

FIGS. 3 (a)-(d) illustrate an example of the simulation results when the temperature characteristics of the crystal resonators are compensated by the compensation curves. In the exemplary embodiments of FIGS. 3 (a)-(d), the narrow solid lines show the original temperature characteristic of the crystal resonator, the broken lines show the compensation curves, and the thick solid lines show the temperature characteristic of the compensated crystal oscillator.

The narrow solid line of FIG. 3 (a) shows an example of the temperature characteristic of the AT-Cut crystal resonator. As shown in FIG. 3 (a), the temperature characteristic of the crystal resonator may have a primarily cubic form, and may fluctuate within the range of −24 ppm to +13 ppm in the temperature range of −40° C. to +85° C. The broken line of FIG. 3 (a) further shows an example of the compensation curve that only includes the quintic term. The thick solid line of FIG. 3 (a) shows an example of the temperature characteristic of the compensated crystal oscillator compensated by the compensation curve. The temperature compensation curve f(T) is expressed by the equation (1):
f(T)=α(T−Ti)⁵+γ (1)

Ti of equation (1) is the temperature at the point of inflexion of the characteristic of the crystal resonator, and is typically about 30° C., and α and γ of equation (1) are the coefficients.

Although it is impossible to completely cancel the cubic temperature characteristic of the crystal resonator with the quintic compensation curve, it is possible to suppress the fluctuation within the range of ±6 ppm at the temperature range of −40° C. to +85° C., as shown in FIG. 3 (a) , which satisfies the specification. This example is a preferred case because Ti of the crystal resonator is equal to that of the compensation curve of the compensation circuit.

The temperature characteristic of the crystal resonator is, however, affected and fluctuates because of the fluctuation in the cutting angle and the production process after the cutout process of the crystal resonator. During the industrial mass-production process of the crystal resonator, it is very difficult to measure the fluctuation of every crystal resonator efficiently and accurately with low cost. Therefore, it frequently occurs that the temperature characteristic of the individual crystal resonator and the compensation curve of the compensation circuit are different. The narrow solid line of FIG. 3 (b) shows the temperature characteristic of the same AT-Cut crystal resonator used in FIG. 3 (a), i.e., the narrow solid line of FIG. 3 (a). The broken line of FIG. 3 (b) shows the compensation curve, in which Ti is shifted by 10° C. higher. The thick solid line of FIG. 3 (b) shows the temperature characteristic of the AT-Cut crystal resonator, in which the compensation curve as shown by the broken line of FIG. 3 (b) is applied to the same AT-Cut crystal resonator as used in FIG. 3 (a). As shown in FIG. 3 (b), it is understood that the above-mentioned specification is satisfied because it fluctuates between −2 ppm and +9 ppm in the temperature range of −40° C. to +85° C., even if the temperature of Ti of the compensation curve is shifted by 10° C. to the higher temperature.

The above-described exemplary embodiment corresponds to a condition where different compensating equations are applied to the same crystal resonator. The result is, however, basically the same in the above described case when the same compensating equation is applied to different crystal resonators.

From the result of the above described case, it appears possible to produce crystal oscillators at low-cost with the circuit that generates the compensation curves including the quintic term under the condition that the fluctuation margin of, for example, 10 ppm in the temperature range of −40° C. to +85° C. is allowed.

Next, the result of simulation of the conventional TCXO that performs the compensation using a compensation curve including primarily a cubic term is described. The narrow solid line of FIG. 3 (c) shows the temperature characteristic of the same crystal resonator as used in FIG. 3 (a). The thick solid line of FIG. 3 (c) shows an example of the temperature characteristic of the crystal oscillator compensated by the compensation curve shown by the broken line of FIG. 3 (c), which includes only a cubic term. As shown by the thick solid line of FIG. 3 (c), the temperature characteristic of the crystal oscillator has a small frequency fluctuation at the temperature range from −40° C. to +85° C.

On the other hand, the narrow solid line of Fig.3 (d) shows the temperature characteristic of the same AT-Cut crystal resonator used in FIG. 3 (c), i.e., the narrow solid line of FIG. 3 (c). The broken line of Fig.3 (d) shows the compensation curve, in which Ti is shifted by 10° C. higher. The thick solid line of Fig.3 (d) shows the temperature characteristic of the AT-Cut crystal resonator, in which the compensation curve as shown by the broken line of Fig. 3 (d) is applied to the same AT-Cut crystal resonator as used in FIG. 3 (c).

When Ti of the compensation curve is shifted by 10° C. to the higher temperature, it is observed from FIG. 3 (d) that the fluctuation of the temperature characteristic is from −1 ppm to +15 ppm for the temperature range of −40° C. to +85° C. From the thick solid line of FIG. 3 (d), it is confirmed that the fluctuation after the compensation in the positive area of the frequency axis is rather large compared to the one before the compensation.

From this result, it is understood that the original frequency-temperature characteristic of the crystal resonators may be worse than the original frequency-temperature characteristic before the compensation and the specification might not be satisfied, when one compensation curve is applied to different crystal resonators by using the circuit which generate the compensation curve composed primarily of the cubic term.

That is, in the conventional TCXO that compensates using a compensation curve including primarily a cubic term, it is indispensable to measure the temperature characteristic of individual crystal resonator, and to adjust the compensation curve.

Another exemplary oscillation circuit is described below.

When the specification of the crystal resonator, such as the tolerable variation of the cutting angle and the fluctuation of the temperature characteristic of the crystal resonator by the productive process is previously known, it is appropriate that the circuit generating the compensation voltage generates the compensation voltage according to one fixed compensation curve. It is, however, desirable to prepare the circuit that generates the compensation voltage according to, for example, two or more different compensation curves in order to manufacture crystal oscillators with crystal resonators of different specifications by using the same circuit to generate compensation voltage.

FIG. 4 shows an example illustrating a block diagram of another exemplary crystal oscillator. The exemplary crystal oscillator shown in FIG. 4 includes a compensation circuit 3 that sets the coefficients of α and γ in equation (1). Each part in FIG. 4, similar to each part of FIGS. 1 and 2, is marked with the same reference number. α, for instance, can be set by controlling the feedback resister of the accumulator 32 according to the coefficient datum stored in the Read Only Memory (ROM) 5 placed in the circuit.

In a switched-capacitance method, for example, the value of γ can be set by placing two or more capacitors in the VCXO, turning the MOS switches on and off, which are placed in series with each capacitor, according to the datum stored in ROM. In another exemplary embodiment, the value of γ can also be set by another method, which comprises adding the offset voltage to the compensation voltage according to the datum stored in ROM. As a result, the capacitance of the variable capacitor in the VCXO circuit 2 is controlled.

According to the present exemplary embodiment, the value of α and γ for each product of the crystal resonators is predetermined by the above-mentioned method. The predetermined values are applied for a plurality of crystal oscillators using crystal resonators prepared with the same specification. As a result, when the crystal resonators in the same production lot are used, it is possible to reduce the fluctuations of the frequency of the crystal oscillators to be within less than ±10 ppm in the temperature range of −40° C. to +85° C., which is the standard operation temperature range of the crystal oscillator, even if the adjustments of each individual crystal resonators are omitted.

As mentioned above, the circuit to generate compensation voltage 3 generates a compensation voltage according to a compensation curve selected among a plurality of predetermined compensation curves including the quintic term.

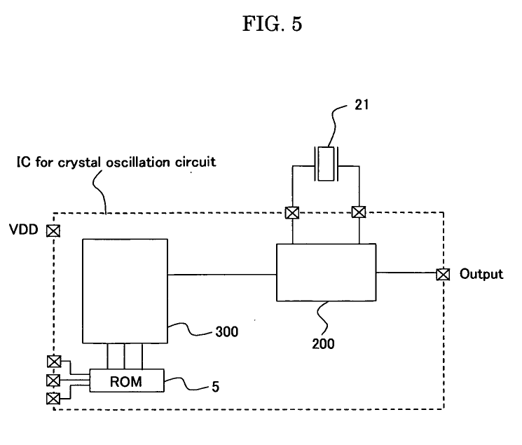

FIG. 5 shows an exemplary construction of an IC that constitutes an exemplary embodiment of the crystal oscillator 1. As shown in FIG. 5, the IC is comprised of a crystal oscillation circuit 200, a circuit to generate a compensation voltage 300 and a ROM 5. All of them may be integrated on a single semiconductor substrate. The circuit that generates the compensation voltage 300 may include a temperature sensor 4, a comparator 31 and accumulator 32, all of which are shown in FIGS. 1 and 2.

Bipolar-type temperature sensors, thermally sensitive resistor-type temperature sensors and others that are conventionally used may be used as the temperature sensor 4. These sensors can be installed on a semiconductor substrate, i.e., they are IC-compatible.

In the above-mentioned exemplary embodiments, the circuit to generate compensation voltage 3 may be an analog circuit. However, the circuit 3 should not be limited to analog circuits, but may also include digital circuits. When a digital circuit is applied for the circuit to generate compensation voltage, the circuit to generate compensation voltage may read the compensating value at each temperature stored in a ROM, for instance, and generate the compensation voltage.

What is claimed is:

1. A method of manufacturing a plurality of crystal oscillators, comprising:
preparing a compensation circuit that generates a common compensation voltage in accordance with a predetermined compensation curve expressed by a quintic polynomial of an ambient temperature; and
manufacturing each of the plurality of crystal oscillators by integrating the compensation circuit with a voltage controlled oscillation circuit including a crystal resonator, the common compensation voltage generated by the compensation circuit being supplied to the voltage controlled oscillation circuit so that the temperature characteristic of the crystal resonator is compensated.

2. The method of manufacturing of claim 1,
wherein the crystal resonator included in the voltage controlled oscillation circuit has a primarily cubic temperature characteristic.

3. The method of manufacturing of claim 1, wherein each of the plurality of crystal oscillators is manufactured without measuring the temperature characteristic of the crystal resonator included in the voltage controlled oscillation circuit.

4. The method of manufacturing of claim 1,
wherein the compensation circuit generates the common compensation voltage in accordance with one of a plurality of prepared compensation curves, each expressed by a quintic polynomial of the ambient temperature.

5. The method of manufacturing of claim 1,
wherein said common compensation voltage compensates the temperature characteristic of the crystal resonator such that a frequency of an output signal of each of the plurality of crystal oscillators comprises a temperature characteristic of less than or equal to ±10 ppm within a temperature range of −40° C. to +85° C.

6. A crystal oscillator comprising:
a voltage controlled crystal oscillation circuit that comprises a crystal resonator; and
a compensation circuit that generates a compensation voltage for compensating the temperature characteristic of the crystal resonator, the compensation voltage being supplied to the voltage controlled crystal oscillation circuit,
wherein the compensation circuit is only composed of a quintic function circuit that generates a voltage having a primarily quintic characteristic of an ambient temperature.

7. The crystal oscillator of claim 6, further comprising a ROM that stores a plurality of adjustment parameters and supplies at least one adjustment parameter selected from the plurality of adjustment parameters to the compensation circuit, wherein:
the quintic finction circuit generates the voltage in accordance with a polynomial of the ambient temperature comprising a quintic term and a constant term; and
at least one of a coefficient of the quintic term and the constant term is adjusted in accordance with the at least one adjustment parameter supplied from the ROM.

8. The crystal oscillator of claim 6, further comprising a ROM that stores a plurality of adjustment parameters and supplies at least one adjustment parameter selected from the plurality of adjustment parameters to the compensation circuit, wherein:
the quintic function circuit generates the voltage in accordance with a polynomial of the ambient temperature including a quintic term, a linear term and a constant term; and
at least one of a coefficient of the linear term and the constant term is adjusted in accordance with the at least one adjustment parameter supplied from the ROM.
